(19) United States
(12) Patent Application Publication
(10) Pub. No.: US 2006/0046207 A1
(43) Pub. Date: Mar. 2, 2006

(54) Exposure method

(75) Inventors: Hsing Tsun Liu, Hsinchu (TW); Hsieh Hsin Huang, Hsinchu (TW); Chon-Shin Jou, Hsinchu (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Mosel Vitelic, Inc., Hsinchu (TW)

(21) Appl. No.: 11/112,454

(22) Filed: Apr. 21, 2005

(30) Foreign Application Priority Data
Aug. 26, 2004 (TW) 093125603

(51) Int. Cl. G03F 7/38; G03F 7/40

(52) U.S. Cl. 430/330

(57) ABSTRACT

Embodiments of the invention are directed to an exposure method for preventing wafer breakage, particularly of a trench-type power MOS device. In one embodiment, the exposure method includes: (a) providing a substrate; (b) forming a trench area and a non-trench area on the substrate; (c) carrying the substrate on a hot plate, the hot plate having a plurality of supporters corresponding to the non-trench area; and (d) performing photoresist coating and baking procedures to the substrate. The exposure method of the present invention can prevent wafer breakage due to rapid temperature variation so as to increase the yield and the efficiency of the manufacturing process and reduce the cost.

### CROSS-REFERENCES TO RELATED APPLICATIONS

This application claims priority from R.O.C. Patent Application No. 093125603, filed Aug. 26, 2004, the entire disclosure of which is incorporated herein by reference.

### BACKGROUND OF THE INVENTION

The present invention relates to an exposure method for preventing wafer breakage, and more particularly to an exposure method for preventing wafer breakage of a trench-typed power MOS device.

The trench-typed power MOS device has been widely developed and applied in recent years. In the preceding manufacturing process of the trench-typed power MOS device, trenches with a width of 2-4 μm and a depth of 30-50 μm are formed on the Epi wafer. Since the aspect ratios of the trenches are high, strong stress is easily caused on the wafer around the trench openings. Especially in the follow-up baking procedure including heating and cooling steps, the rapid temperature variation induces thermal shock, which will destroy the lattice structure around the trench openings and cause wafer breakage.

For example, in the photoresist coating and baking procedures of the trench-typed power MOS device, the wafer having trenches and under room temperature is heated to 200° C. for dehydration baking for about 100 seconds first, and then cooled down to room temperature. Subsequently, the wafer is coated with hexamethyldisilazane (HMDS) and then placed on a hot plate to be heated to 90° C. for baking. After baking for about 100 seconds, the wafer is cooled down to room temperature and then coated with photoresist. Afterward, the wafer coated with photoresist is heated to 90° C. for soft baking for about 100 seconds, and then cooled down to room temperature. However, the wafer is usually broken during the baking procedure after the photoresist coating procedure, and the initiation points of the cracks on different wafers are substantially the same.

FIG. 1 is a schematic view showing the cracks on the wafer after the baking procedure. The wafer 1 is placed on a hot plate 3 during the baking procedure for carrying the wafer 1 to move up and down for baking. Since the hot plate carries the wafer 1 via three supporters 4, after the heating and cooling steps, the portions of the wafer that the three supporters of the hot plate contact will bear the stress caused from the up and down movement of the hot plate and the rapid temperature variation. Accordingly, the lattice structure around the trench openings on the wafer 1 corresponding to the three supporters will be destroyed, and the cracks 14 will be formed outwardly on the wafer 1 from the trench openings as the breakage points 11, 12 and 13. As a result, the wafer cannot be used, which reduces the yield and increases the cost.

Therefore, a solution is needed for preventing wafer breakage during the manufacturing process of a trench-typed power MOS device.

### BRIEF SUMMARY OF THE INVENTION

A feature of the present invention is to provide an exposure method for preventing wafer breakage of a trench-typed power MOS device. The exposure method of the present invention can prevent wafer breakage due to rapid temperature variation so as to increase the yield and the efficiency of the manufacturing process and reduce the cost.

According to an aspect of the present invention, an exposure method includes: (a) providing a substrate; (b) forming a trench area and a non-trench area on the substrate; (c) carrying the substrate on a hot plate, the hot plate having a plurality of supporters corresponding to the non-trench area; and (d) performing photoresist coating and baking procedures to the substrate.

The present invention will be illustrated in the following drawings and embodiments, but the processes, steps, materials, sizes, structures or other optional parts described in the embodiments are not used to confine the present invention; furthermore, the present invention is defined by the appended claims.

### BRIEF DESCRIPTION OF THE DRAWINGS

FIG. 1 is a schematic view showing the cracks on the wafer after the baking procedure.

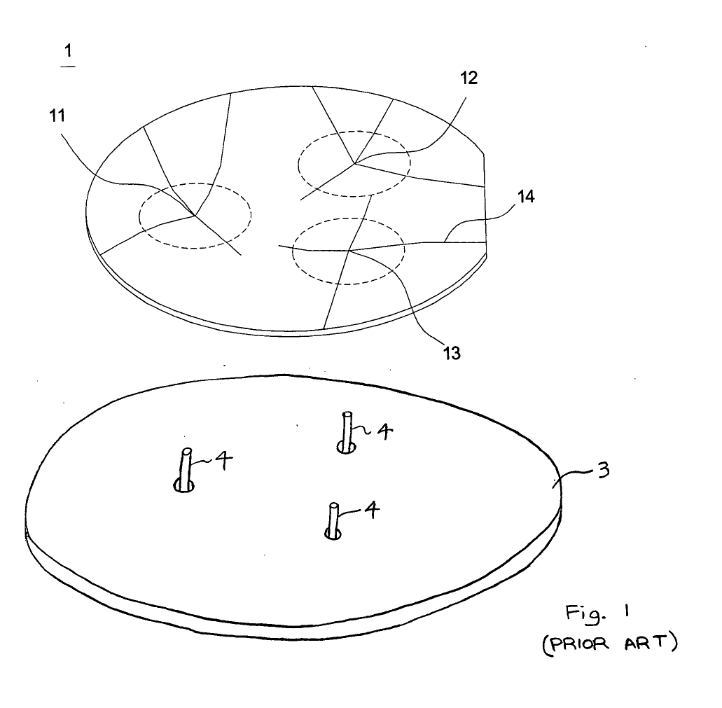

FIGS. 2(a)-(b) are schematic views showing the non-trench area having different shapes formed on the wafer by the exposure method according to an embodiment of the present invention.

FIGS. 3(a)-(b) are schematic views showing the non-trench area having different shapes formed on the wafer by the exposure method according to another embodiment of the present invention.

### DETAILED DESCRIPTION OF THE INVENTION

Some typical embodiments to present the features and advantages of the present invention will be particularly described in the following illustrations. It should be understood that the present invention may have various modifications in different modes, which are not apart from the scope of the present invention, and the illustrations and drawings of the present invention are substantially used for explaining but not for limiting the present invention.

The present invention provides an exposure method which can prevent wafer breakage and can be applied to the manufacturing process of the trench-typed power MOS device. The exposure method of the present invention includes the following steps. First, a substrate is provided and a photoresist layer is formed on the substrate. Then, an exposure area and a non-exposure area are defined and a photolithography procedure is performed so as to form a trench area and a non-trench area on the substrate. Subsequently, the substrate is carried on a hot plate and the plurality of supporters of the hot plate correspond to the non-trench area of the substrate. Afterward, the photoresist coating and baking procedures are performed to the substrate to facilitate the following manufacturing process of the trench-typed power MOS device.

In the photoresist coating and baking procedures of the trench-typed power MOS device, the wafer having trenches and under room temperature is heated to about 200° C. for dehydration baking for about 100 seconds first, and then cooled down to room temperature. Subsequently, the wafer is coated with hexamethyldisilazane (HMDS) and then placed on a hot plate to be heated to about 90° C. for baking. After baking for about 100 seconds, the wafer is cooled down to room temperature and then coated with photoresist. Afterward, the wafer coated with photoresist is heated to about 90° C. for soft baking for about 100 seconds, and finally cooled down to room temperature.

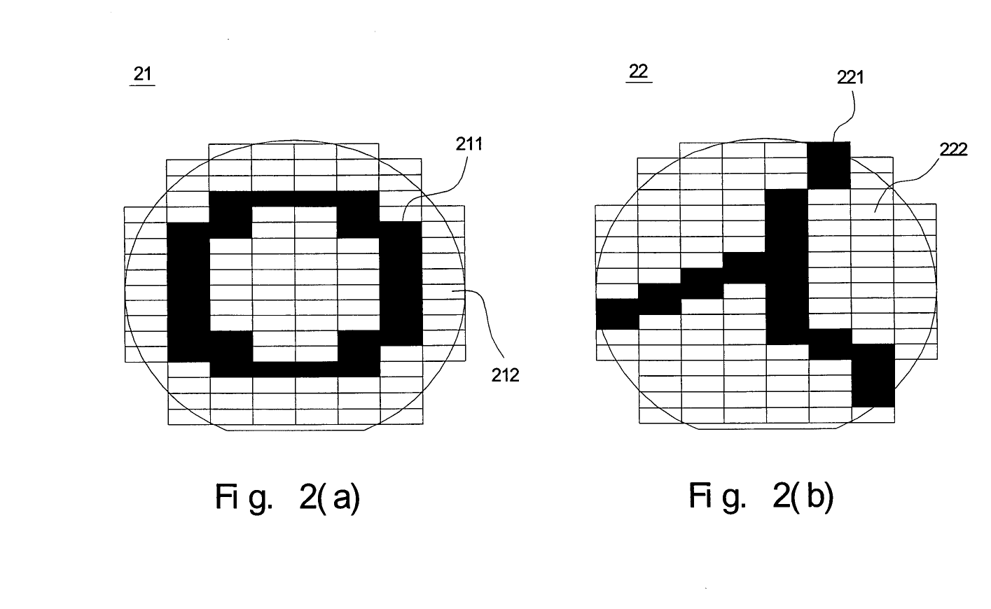

FIGS. 2(a)-(b) are schematic views showing the non-trench area having different shapes formed on the wafer by the exposure method according to an embodiment of the present invention. The wafer 21, 22 includes a non-trench area 211, 221 and a trench area 212, 222 thereon, respectively. The non-trench area 211, 221 is formed by the above-described manufacturing process, and the shape of the non-trench area can be any geometric shape that covers the plurality of supporters of the hot plate carrying the wafer. Preferably, the shape of the non-trench area 211, 221 is O-shaped or Y-shaped, but not limited thereto. Since the plurality of supporters of the hot plate contact the wafer only at the non-trench area 211, 221 which has no trench therein, the portions of the wafer that the plurality of supporters of the hot plate contact will not be broken due to the up and down movement of the hot plate and the rapid temperature variation. Thus, the yield can be increased and the cost can be saved.

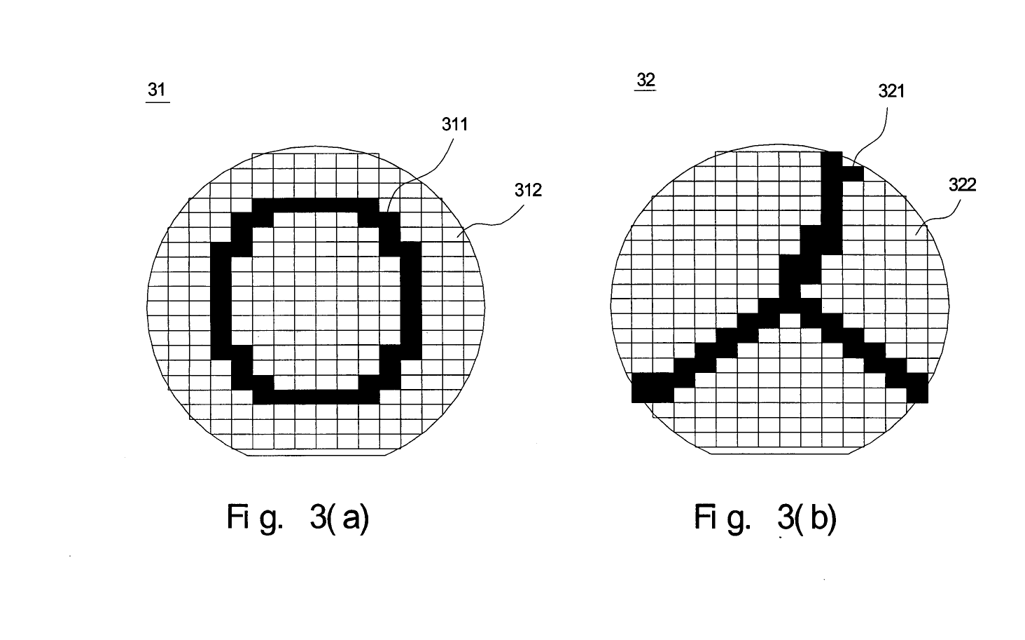

FIGS. 3(a)-(b) are schematic views showing the non-trench area having different shapes formed on the wafer by the exposure method according to another embodiment of the present invention. The wafer 31, 32 also includes a non-trench area 311, 321 and a trench area 312, 322 thereon, respectively. The non-trench area 311, 321 is formed by the above-described manufacturing process, and the shape of the non-trench area can be any geometric shape that covers the plurality of supporters of the hot plate carrying the wafer. Preferably, the shape of the non-trench area 311, 321 is O-shaped or Y-shaped, but not limited thereto. Similarly, since the plurality of supporters of the hot plate contact the wafer only at the non-trench area 311, 321 which has no trench therein, the portions of the wafer that the plurality of supporters of the hot plate contact will not be broken due to the up and down movement of the hot plate and the rapid temperature variation. Thus, the yield can be increased and the cost can be saved.

Particularly, the difference between the embodiments of FIGS. 3(a)-(b) and FIGS. 2(a)-(b) is that the reduction ratio of the projection lens is altered. In this embodiment, the number of the lattices per unit area is increased, so the area of the non-trench area 311, 312 is decreased, and thus the number of the waste chips can be lowered, so as to increase the yield and efficiency of the manufacturing process.

In conclusion, the trench area and the non-trench area are formed on the wafer of the trench-typed power MOS device by the exposure method of the present invention, so that in the subsequent photoresist coating and baking procedures, the wafer breakage due to the up and down movement of the hot plate and the rapid temperature variation can be largely prevented since the plurality of supporters of the hot plate correspond to the non-trench area of the wafer. Therefore, the yield and the efficiency of the manufacturing process can be increased and the cost can be reduced.

It is to be understood that the above description is intended to be illustrative and not restrictive. Many embodiments will be apparent to those of skill in the art upon reviewing the above description. The scope of the invention should, therefore, be determined not with reference to the above description, but instead should be determined with reference to the appended claims along with their full scope of equivalents.

What is claimed is:

1. An exposure method, comprising:
providing a substrate having a trench area and a non-trench area;
carrying said substrate on a hot plate, said hot plate having a plurality of supporters corresponding to said non-trench area; and
performing photoresist coating and baking procedures to said substrate.

2. The exposure method of claim 1 wherein said substrate is a wafer.

3. The exposure method of claim 1 wherein providing the substrate comprises:
forming a photoresist layer on said substrate; and
defining an exposure area and a non-exposure area and performing a photolithography procedure to form said trench area and said non-trench area on said substrate.

4. The exposure method of claim 1 wherein said non-trench area is substantially in O-shape or Y-shape.

5. The exposure method of claim 1 wherein performing the photoresist coating and backing procedures further comprises:
heating said substrate for dehydration baking;
cooling said substrate;
coating said substrate with hexamethyldisilazane (HMDS);
heating said substrate for baking;
cooling said substrate and coating said substrate with photoresist;
heating said substrate coated with said photoresist for soft baking; and
cooling said substrate.

6. A method for manufacturing a trench-typed power MOS device, comprising:
providing a substrate;
forming a trench area and a non-trench area on said substrate;
carrying said substrate on a hot plate, said hot plate having a plurality of supporters corresponding to said non-trench area; and
performing photoresist coating and baking procedures to said substrate.

7. The method of claim 6 wherein said substrate is a wafer.

8. The method of claim 6 wherein forming the trench area and non-trench area further comprises:
forming a photoresist layer on said substrate; and
defining an exposure area and a non-exposure area and performing a photolithography procedure to form said trench area and said non-trench area on said substrate.

9. The method of claim 6 wherein said non-trench area is substantially in O-shape or Y-shape.

10. The method of claim 6 wherein performing photoresist coating and baking procedures comprises:
heating said substrate for dehydration baking;
cooling said substrate;
coating said substrate with hexamethyldisilazane (HMDS);
heating said substrate for baking;
cooling said substrate and coating said substrate with photoresist;
heating said substrate coated with said photoresist for soft baking; and
cooling said substrate.

11. An exposure method, comprising:
providing a substrate having a trench area and a non-trench area;
providing a hot plate;
placing the substrate on the hot plate to be supported by the plurality of supporters at the non-trench area; and
performing photoresist coating and baking procedures to the substrate.

12. The exposure method of claim 11 wherein the substrate is a wafer.

13. The exposure method of claim 11 wherein providing the substrate comprises:
forming a photoresist layer on said substrate; and
defining an exposure area and a non-exposure area and performing a photolithography procedure to form said trench area and said non-trench area on said substrate.

14. The exposure method of claim 11 wherein said non-trench area is substantially in O-shape or Y-shape.

15. The exposure method of claim 11 wherein performing the photoresist coating and backing procedures further comprises:
heating said substrate for dehydration baking;
cooling said substrate;
coating said substrate with hexamethyldisilazane (HMDS);
heating said substrate for baking;
cooling said substrate and coating said substrate with photoresist;
heating said substrate coated with said photoresist for soft baking; and
cooling said substrate.
